(19) United States
(12) Patent Application Publication
(10) Pub. No.: US 2009/0087991 A1
(43) Pub. Date: Apr. 2, 2009

(54) Manufacturing method, manufacturing apparatus, control program and program recording medium of semicontructor device

(75) Inventors: Koichi Yatsuda, Nirasaki-shi (JP); Eiichi Nishimura, Nirasaki-shi (JP)

Correspondence Address: MASUVALLEY & PARTNERS, 8765 AERO DRIVE, SUITE 312, SAN DIEGO, CA, 92123, US

(73) Assignee: TOKYO ELECTRON LIMITED, Minato-ku (JP)

(21) Appl. No.: 12/284,750

(22) Filed: Sep. 24, 2008

Related U.S. Application Data
(60) Provisional application No. 60/991,476, filed on Nov. 30, 2007.

(30) Foreign Application Priority Data
Sep. 28, 2007 (JP) 2007-253410

(51) Int. Cl. H01L 21/3105

(52) U.S. Cl. 438/694; 156/345.26; 257/E21.219; 257/E21.09

(57) ABSTRACT

A manufacturing method of a semiconductor device, which etches a layer to be etched on a substrate into a predetermined pattern based on a first pattern of photoresist produced by exposing and developing a photoresist film, the manufacturing method includes the steps of, patterning an organic membrane based on a first pattern of the photoresist, forming an SiO₂ film on the patterned organic membrane, etching the SiO₂ film so that the SiO₂ remains only in a side wall section of the organic membrane and forming a second pattern of the SiO₂ film by removing the organic membrane.

### BACKGROUND OF THE INVENTION

1. Technical Field

The present invention relates to a manufacturing method of a semiconductor device, a manufacturing apparatus for manufacturing a semiconductor device, a control program, and a recording medium for the program for manufacturing a semiconductor device by etching a layer to be etched on a substrate into a predetermined pattern based on a first pattern of a photoresist produced by exposing and developing a photoresist film.

2. Description of the Related Art

Up to now, in manufacturing processes, such as a semiconductor device, etching processing of plasma etching to substrates, such as a semiconductor wafer, has been performed to form a fine circuit pattern. In such an etching processing process, an etching mask is formed by performing a photolithography process using photoresist.

In such a photolithography process, in order to respond to the trend toward a fine pattern to be formed, various technologies have been developed. There is what is called double patterning as one of them. This double patterning is a pattering process, which is capable of forming an etching mask having a more fine pattern than a case where an etching mask is formed by one patterning by performing two steps of patterning including the first mask pattern formation step and the second mask pattern formation step performed after this first mask pattern formation step. (For example, refer to Japanese Patent Application Publication No. 2007-027742)

It has been known to perform patterning in a pitch more fine than a pattern of photoresist obtained by firstly exposing and developing a photoresist film by using an SWT (side wall transfer) method which uses SiO₂ film, Si₃N₄ film, etc., as a sacrificial layer, for example, and forms and uses a mask for both-side side wall portions of one pattern. That is, in this method, a sacrificial layer of SiO₂ film is etched and patterned first, using a pattern of photoresist. After that, an Si₃N₄ film, etc., is formed on a pattern of this SiO₂ film, and etchback is performed so that Si₃N₄ film may remain only in a side wall portion of SiO₂ film. Then, wet etching removes SiO₂ film and lower layer etching is performed by using the Si₃N₄ remaining film as a mask.

In membrane formation technologies, it may be required that membranes should be formed more at low temperature. With regard to a technology for performing a formation of membranes at low temperature, a method for performing membrane formation with chemicals vapor phase epitaxy, in which membrane formation gas is activated by a heating catalyst body, is known (for example, refer to Japanese Patent Application Publication No. 2006-179819).

In a conventional technology, as described above, there are problems that the number of processes increases, while a process is complicated, a manufacturing cost increases, and productivity becomes worse. In the conventional SWT method, since a wet etching process is required, it becomes a process in which dry etching and wet etching are intermingled. This becomes a factor, which makes a process complicated.

An object of the present invention is to provide a manufacturing method of a semiconductor device, a manufacturing apparatus of a semiconductor device, a control program, and a program store medium which can promote improvement in productivity to solve the conventional problems described above and to perform simplification of a process and reduction of a manufacturing cost comparing with the former.

### SUMMARY OF THE INVENTION

An aspect of the present invention is a manufacturing method of a semiconductor device, which etches a layer to be etched on a substrate into a predetermined pattern based on a first pattern of photoresist produced by exposing and developing a photoresist film. The manufacturing method includes the steps of patterning an organic membrane based on a first pattern of the photoresist, forming an SiO₂ film on the patterned organic membrane, etching the SiO₂ film so that the SiO₂ remains only in a side wall section of the organic membrane, and forming a second pattern of the SiO₂ film by removing the organic membrane.

Another aspect of the present invention is a manufacturing method of a semiconductor device, wherein the step of forming an SiO₂ film is performed by applying chemical vapor phase epitaxy by using membrane formation gas activated by a heating catalyst body.

Another aspect of the present invention is a manufacturing method of a semiconductor device, wherein a silicon layer, a silicon nitride layer, an silicon oxynitride layer (SiON), or a silicon dioxide layer (SiO₂), which is a lower layer, is etched by using the second pattern as a mask after the step of forming a second pattern.

Another aspect of the present invention is a manufacturing method of a semiconductor device,

wherein the step of patterning an organic membrane is performed by etching an antireflection film formed by an inorganic material, which is a lower layer, by using a first pattern of the photoresist as an etching mask and then etching the organic membrane by using an antireflection film which is formed by the inorganic material as an etching mask.

Another aspect of the present invention is a manufacturing method of a semiconductor device,

wherein trimming of the organic membrane is performed in a situation where an etching mask of an antireflection film formed by the inorganic material has been formed on the organic membrane.

Another aspect of the present invention is a manufacturing method of a semiconductor device,

wherein an antireflection film formed by the inorganic material is an SOG (Spin On Glass) film, an SiON (silicon oxynitride) film or a composite membrane of an LTO (Low Temperature Oxide) film, and BARC (Bottom Anti-Reflective Coating).

Another aspect of the present invention is a manufacturing apparatus of a semiconductor device, which manufactures a semiconductor device by etching a layer to be etched on a substrate into a predetermined pattern. The manufacturing apparatus includes a processing chamber for storing the substrate, a processing gas supply means, which supplies processing gas into the processing chamber, and a control section for controlling the processing gas supply means so that the manufacturing method of a semiconductor device is performed within the processing chamber.

Another aspect of the present invention is a control program for operating on a computer and controlling a manufacturing apparatus of a semiconductor device at time of execution so that a manufacturing method of semiconductor device is performed.

Another aspect of the present invention is a program store medium, which is a medium by which a control program, which operates on a computer, is memorized, and the control program controlling a manufacturing apparatus of a semiconductor device so that a manufacturing method of the semiconductor device is performed at time of execution.

### BRIEF DESCRIPTION OF THE DRAWINGS

FIG. 1 schematically illustrates a process of a first embodiment of the present invention.

FIG. 2 schematically illustrates a process of a second embodiment of the present invention.

FIG. 3 schematically illustrates a process of a third embodiment of the present invention.

FIG. 4 schematically illustrates a process of a fourth embodiment of the present invention.

FIG. 5 schematically illustrates a schematic diagram of the apparatus used for one embodiment of the present invention.

### DETAILED DESCRIPTION OF THE PREFERRED EMBODIMENTS

Hereafter, embodiments of the present invention will be described by using drawings as references.

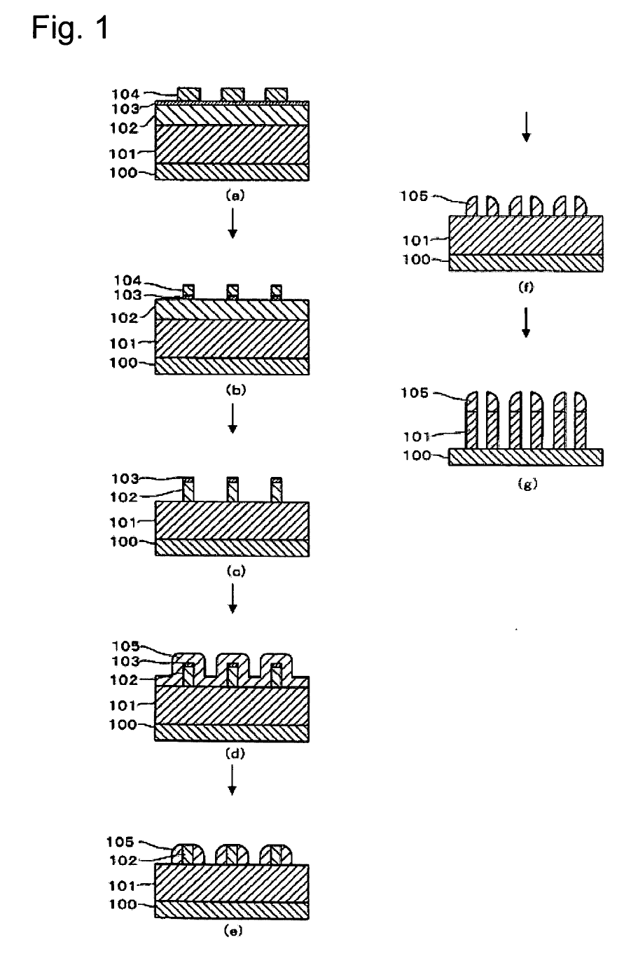

FIG. 1 is a drawing, which expands and schematically illustrates a part of a semiconductor wafer related to a first embodiment of the present invention, and illustrates a process of a manufacturing method of a semiconductor device related to the first embodiment. As illustrated in FIG. 1 (a), in this first embodiment, an organic membrane 102 is formed on a polysilicon layer 101 as a layer to be etched for aiming at patterning. On this organic membrane 102, an SOG film (or an SiON film or a composite membrane of an LTO film and BARC) 103 is formed as an antireflection film formed from inorganic materials. A photoresist 104 is formed on the SOG film (or a SiON film or the composite membrane of an LTO film and BARC) 103. The photoresist 104 is patterned by an exposure and development process and formed into a pattern having a predetermined shape. In FIG. 1, numeral 100 denotes a foundation layer provided under the polysilicon layer 101.

For example, FIG. 1 (b) illustrates a state where trimming of the above-mentioned photoresist 104 is performed using plasma, such as oxygen gas or nitrogen gas, to make a line width thin, and then an SOG film (or an SiON film or a composite membrane of a LTO film and BARC) 103 is etched after this. Etching of this SOG film (or an SiON film or the composite membrane of an LTO film and BARC) 103, for example, can be carried out by using mixed gas of CF series gas, such as CF₄, C₄F₈, CHF₃, CH₃F, and CH₂F₂, and Ar gas and/or the gas that oxygen is added if needed to this mixed gas.

Next, as illustrated in FIG. 1 (c), the organic membrane 102 is etched by using the above-mentioned SOG film (or an SiON film or the composite membrane of an LTO film and BARC) 103 as a mask. The plasma etching, which uses plasma, such as oxygen gas or nitrogen gas, can perform etching of the organic membrane 102.

Next, as illustrated in FIG. 1 (d), an SiO₂ film 105 is formed.

As for organic membrane 102, generally, although membranes are formed on the organic membrane 102 in this membrane formation process, since the organic membrane 102 is weak to high temperature, it is preferred to form membranes at low temperature (for example, about 300 degrees centigrade or less). In this case, the chemical vapor phase epitaxy in which membrane formation gas is activated by the heating catalyst body can be performed.

Next, as illustrated in FIG. 1 (e), the SiO₂ film 105 is etched and the SiO₂ film 105 changes into the state where the SiO₂ film 105 remains only on the side wall section of the pattern of organic membrane 102. In this case, the SOG film (or an SiON film or the composite membrane of an LTO film and BARC) 103 used as an etching mask of the organic membrane 102 is also etched and removed. This etching can be performed by using a mixed gas, for example, CF series gas of CF₄, C₄F₈, CHF₃, CH₃F, and CH₂F₂, and Ar gas and/or the gas that oxygen is added if needed to this mixed gas.

Next, as illustrated in FIG. 1 (f), by etching using plasma, such as oxygen gas or nitrogen gas, etc., the pattern of the organic membrane 102 is removed and the pattern of the SiO₂ film 105, which remained in the side-wall section, is formed.

And as illustrated in FIG. 1 (g), the lower layer polysilicon layer 101 is etched by using the pattern of the SiO₂ above-mentioned film 105 as a mask. This etching can be performed using plasma, such as HBr gas, for example.

The fine pattern by the SWT method can be formed in the above-mentioned first embodiment, without performing wet etching in the middle of a process. Thus, in a first embodiment, all etching processes can be carried out according to a dry etching process, without performing wet etching in the middle of a process. Therefore, simplification of a process and reduction of a manufacturing cost can be promoted comparing with the former, and improvements in productivity can be promoted.

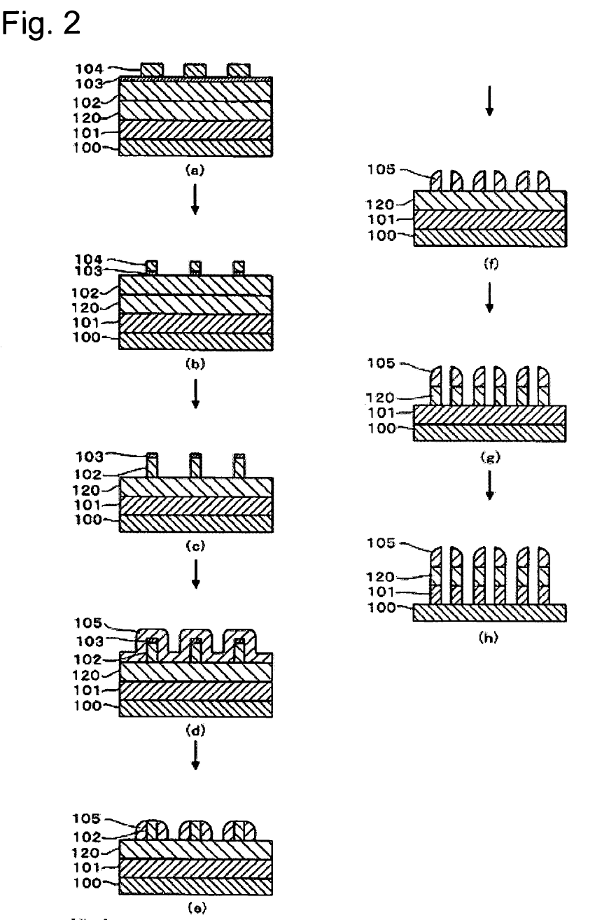

FIG. 2 illustrates the manufacturing process of the semiconductor device of a second embodiment in which another film 120, for example, an Si₃N₄ film, is formed between the polysilicon layer 101 and the organic membrane 102 in the above-mentioned first embodiment. In the case of this second embodiment, the process of FIGS. 2 (a)-2(f) is performed as well as the case of a first embodiment illustrated in FIG. 1. And after this, a lower layer Si₃N₄ film 120 is etched (g) by using the pattern by the SiO₂ film 105 as a mask, and the polysilicon layer 101 is etched (h) by using this Si₃N₄ film 120 as a mask (h). In the case of FIG. 2, an SiON (silicon oxynitride) film may be used instead of the Si₃N₄ film 120. Instead of the Si₃N₄ film 120, an SiO₂ (silicon dioxide) film may also be used.

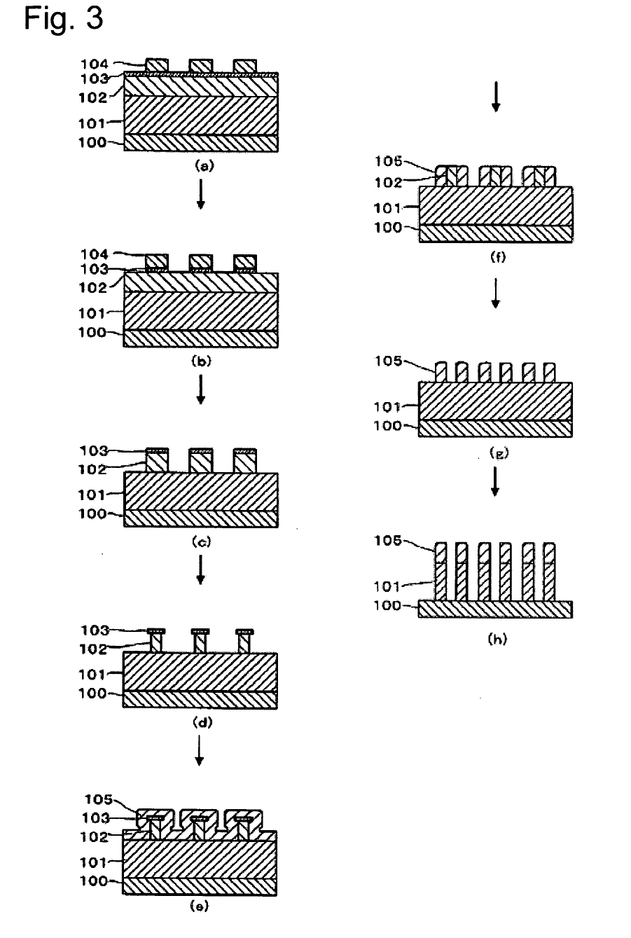

FIG. 3 illustrates the process of a third embodiment which altered a part of order of the process in the above-mentioned first embodiment. As illustrated in FIG. 3(a), in this third embodiment, the organic membrane 102 is formed on the polysilicon layer 101 as a layer aiming at patterning to be etched as well as the first embodiment. On this organic membrane 102, the SOG film (or an SiON film or the composite membrane of an LTO film and BARC) 103 is formed as an antireflection film formed from inorganic materials, and photoresist 104 is formed on the SOG film (or a SiON film or the composite membrane of an LTO film and BARC) 103. The photoresist 104 is patterned by exposure and development process, and, is formed into a pattern having a predetermined shape. In FIG. 3, numeral 100 denotes the foundation layer provided under the polysilicon layer 101.

As illustrated in FIG. 3(b), in this third embodiment, the SOG film (or an SiON film or the composite membrane of an LTO film and BARC) 103 is first etched by using the photoresist 104 as a mask. Etching of this SOG film (or an SiON film or the composite membrane of an LTO film and BARC) 103, for example, can be carried out by using mixed gas of CF series gas, such as, CF₄, C₄F₈, CHF₃, CH₃F, and CH₂F₂, and Ar gas and/or the gas that oxygen is added if needed to this mixed gas.

Next, as illustrated in FIG. 3(c), plasma etching of the organic membrane 102 is performed using plasma, such as oxygen gas or nitrogen gas, for example, by using the SOG film (or an SiON film or the composite membrane of an LTO film and BARC) 103 as a mask. Then, as illustrated in FIG. 3 (d), trimming of the organic membrane 102 is performed by the above-mentioned plasma, etc., and line width is made thin. This trimming is performed under the situation where the upper portion of the organic membrane 102 is covered with the SOG film (or an SiON film or the composite membrane of an LTO film and BARC) 103 as a mask. Therefore, without performing perpendicular etching of organic membrane 102, and without decreasing film thickness, only line width can be made thin and trimming is performed in the lateral direction. Therefore, the SiO₂ film 105 as a hardmask, which will be described later, can be thickly formed perpendicularly.

Next, as illustrated in FIG. 3 (e), an SiO₂ film 105 is formed.

In order to form membranes on the organic membrane 102 in this membrane formation process, as mentioned above, it is preferred to form membranes at low temperature (for example, about 300 degrees centigrade or lower). And this membrane formation process is preferred to be carried out with the chemicals vapor phase epitaxy in which membrane formation gas is activated by the heating catalyst body.

Next, as illustrated in FIG. 3 (f), the SiO₂ film 105 and the SOG film (or the SiON film or the composite membrane of an LTO film and BARC) 103 are etched, and the SiO₂ film 105 changes into the state where the SiO₂ film 105 remains only in the side wall section of the pattern of the organic membrane 102. This etching can be performed by using the mixed gas, such as, CF series gas, for example, CF₄, C₄F₈, CHF₃, CH₃F, and CH₂F₂ and Ar gas and/or the gas that oxygen is added if needed to this mixed gas. Since membrane formation of the SiO₂ film 105, and etching of the SiO₂ film 105 and the SOG film (or an SiON film or the composite membrane of an LTO film and BARC) 103 are performed under the situation where the SOG film (or an SiON film or the composite membrane of an LTO film and BARC) 103 has been formed on organic membrane 102, the side wall of the SiO₂ remaining film 105 can be formed perpendicularly.

Next, as illustrated in FIG. 3 (g), by etching using plasma, such as oxygen gas or nitrogen gas, etc., the pattern of the organic membrane 102 is removed and the pattern by the SiO₂ film 105 which remained in the side-wall section is formed.

And as illustrated in FIG. 3(h), the polysilicon layer 101, which is a lower layer, is etched by using the pattern by the above-mentioned SiO₂ film 105 as a mask. This etching can be performed using plasma, such as HBr gas, for example.

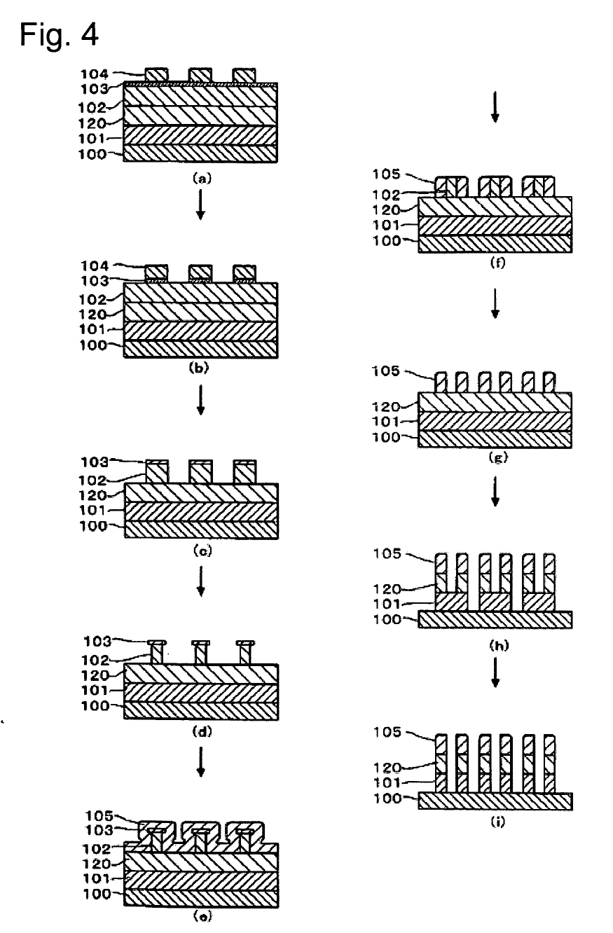

FIG. 4 illustrates a manufacturing process of the semiconductor device of a fourth embodiment with which another film 120, for example, an Si₃N₄ film, is formed between the polysilicon layer 101 and the organic membrane 102 in the above-mentioned third embodiment. In the case of this fourth embodiment, the process of FIG. 4 (a)-(g) is performed as well as the case of the third embodiment illustrated in FIG. 3. And, after this, the Si₃N₄ film 120, which is a lower layer, is etched by using the pattern by the SiO₂ film 105 as a mask (h). After that, the polysilicon layer 101 is etched by using this Si₃N₄ film 120 etc, as a mask (i). As described above, the membrane formation of SiO₂ film 105, and the etching of the SiO₂ film 105 and the SOG film (or a SiON film or the composite membrane of a LTO film and BARC) 103 are performed under the situation where the SOG film (or an SiON film or the composite membrane of an LTO film and BARC) 103 has been formed on organic membrane 102. Thus, the side wall of SiO₂ film 105 which remained can be formed perpendicularly. In the first to fourth embodiments, although the film 103 has been described as an antireflection film formed from inorganic materials, the function as an antireflection film may not be in this film 103. For example, the film 103 may be a single independent LTO film.

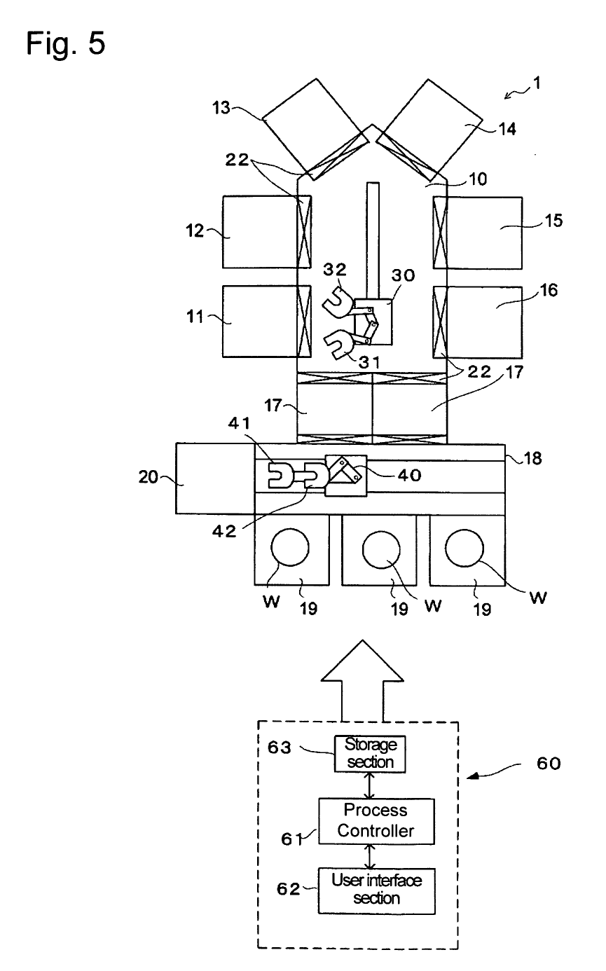

FIG. 5 is a top view schematically illustrating an example of the structure of the manufacturing apparatus of the semiconductor device for performing the manufacturing method of the above-mentioned semiconductor device. A vacuum conveyance chamber 10 is provided in the central portion of the manufacturing apparatus 1 of a semiconductor device. Along with this vacuum conveyance chamber 10, a plurality of processing chambers 11-16 (in this embodiment, they are six pieces) are disposed in that circumference. These processing chambers 11-16 perform chemical vapor phase epitaxy in which membrane formation gas is activated inside by plasma etching and a heating catalyst body.

Two load lock chambers 17 are provided in this side (the lower side in FIG. 5) of a vacuum conveyance chamber 10. A conveyance chamber 18 for conveying a substrate (in this embodiment, a semiconductor wafer W) in the atmosphere is provided further in this side of those load lock chambers 17 (the lower side in FIG. 5). Further in this side of the conveyance chamber 18 (the lower side in FIG. 5), a plurality of placing sections 19, onto which a substrate storing case (a cassette or a hoop), into which a plurality of semiconductor wafers W can be stored, is disposed is provided (in FIG. 5, there are three placing sections). An orienter 20, which detects the position of semiconductor wafer W by an orientation flat or a notch, is provided in the side of the conveyance chamber 18 (left-hand side in FIG. 5).

A gate valve 22 is respectively provided between the vacuum conveyance chamber 10 and the processing chambers 11-16, between the load lock chamber 17 and the vacuum conveyance chamber 10 and between the load lock chamber 17 and the conveyance chamber 18. Between these spaces can be arranged to be air-tightly blockaded and opened. A vacuum conveyance mechanism 30 is provided in the vacuum conveyance chamber 10. This vacuum conveyance mechanism possesses a first pick 31 and a second pick 32. The vacuum conveyance mechanism 30 is configured so that two semiconductor wafers are supported. The vacuum conveyance mechanism 30 is configured so that the semiconductor wafer W can be carried in and taken out to each processing chambers 11-16 and load lock chamber 17.

An air conveyance mechanism 40 is provided in the conveyance chamber 18. This air conveyance mechanism 40 possesses a first pick 41 and a second pick 42, and these configure the air conveyance mechanism 40 so as to be able to support two semiconductor wafers W. The air conveyance mechanism 40 is configured so that semiconductor wafer W can be carried in and taken out to each cassette or the hoop, the load lock chamber 17 and the orienter 20, which are placed in the placing section 19.

The operation of the manufacturing apparatus 1 of the semiconductor device having the above-mentioned structure is totally controlled by a control section 60. A process controller 61, which is provided with CPU for controlling each section of the manufacturing apparatus 1 of the semiconductor device, a user interface section 62 and a storage section 63 are provided in this control section 60.

The user interface section 62 is configured by a keyboard which performs input operation of a command in order that a process controller may control the manufacturing apparatus 1 of the semiconductor device, a display which visualizes and displays the operation status of manufacturing apparatus 1 of the semiconductor device, etc.

The recipe, with which a control program (software), processing condition data, etc. for realizing various processes executed by the manufacturing apparatus 1 of the semiconductor device through the control of the process controller 61 have been memorized, is stored in a storage section 63. And when needed, arbitrary recipes are called from the storage section 63 with the directions from the user interface section 62, etc., and the process controller 61 is executed. Thereby, a desired processing by the manufacturing apparatus 1 of the semiconductor device is performed under the control of the process controller 61. Recipes, such as a control program and processing condition data, use the data in the state where the data has been stored in the program store media (for example, a hard disk, CD, a flexible disk, semiconductor memory, etc.), etc. which can be read by computers. Or it is also possible to make the data transmit at any time via a dedicated line, for example, and to use on-line from other apparatuses.

A series of processes illustrated in the first to the four embodiments can be carried out by using the manufacturing apparatus 1 of the semiconductor device of the above-mentioned structure. Semiconductor wafer W may once be taken out from the manufacturing apparatus 1 of the above-mentioned semiconductor device, and other apparatus may perform a membrane formation process.

The present invention has been presented in order to solve the above-mentioned problems. According to embodiments of the present invention, simplification of a process and reduction of a manufacturing cost can be promoted comparing to the former. The manufacturing method of the semiconductor device, which can promote improvements in productivity, the manufacturing apparatus of a semiconductor device, a control program and a program store medium can also be provided.

What is claimed is:

1. A manufacturing method of a semiconductor device, which etches a layer to be etched on a substrate into a predetermined pattern based on a first pattern of photoresist produced by exposing and developing a photoresist film, the manufacturing method comprising the steps of:
patterning an organic membrane based on a first pattern of the photoresist;
forming an SiO₂ film on the patterned organic membrane;
etching the SiO₂ film so that the SiO₂ remains only in a side wall section of the organic membrane; and
forming a second pattern of the SiO₂ film by removing the organic membrane.

2. The manufacturing method of a semiconductor device of claim 1,
wherein the step of forming an SiO₂ film is performed by applying chemical vapor phase epitaxy by using membrane formation gas activated by a heating catalyst body.

3. The manufacturing method of a semiconductor device of claim 1,
wherein a silicon layer, a silicon nitride layer, a silicon oxynitride layer or a silicon dioxide layer, which is a lower layer, is etched by using the second pattern as a mask after the step of forming a second pattern.

4. The manufacturing method of a semiconductor device of claim 1,
wherein the step of patterning an organic membrane is performed by etching an antireflection film formed by an inorganic material, which is a lower layer by using a first pattern of the photoresist as an etching mask and then etching the organic membrane by using an antireflection film which is formed by the inorganic material as an etching mask.

5. The manufacturing method of a semiconductor device of claim 4,
wherein trimming of the organic membrane is performed in a situation where an etching mask of an antireflection film formed by the inorganic material has been formed on the organic membrane.

6. The manufacturing method of a semiconductor device of claim 4,
wherein an antireflection film formed by the inorganic material is an SOG film, an SiON film or a composite membrane of an LTO film and BARC.

7. A manufacturing apparatus of a semiconductor device, which manufactures a semiconductor device by etching a layer to be etched on a substrate into a predetermined pattern, the manufacturing apparatus comprising:
a processing chamber for storing the substrate;
a processing gas supply means, which supplies processing gas into the processing chamber; and
a control section for controlling the processing gas supply means so that the manufacturing method of a semiconductor device as in any one of claims 1-6, is performed within the processing chamber.

8. A control program for operating on a computer and controlling a manufacturing apparatus of a semiconductor device at time of execution so that the manufacturing method of the semiconductor device as in any one of claims 1-6 is performed.

9. A program store medium, which is a medium by which a control program, which operates on a computer, is memorized, the control program controlling a manufacturing apparatus of a semiconductor device so that the manufacturing method of the semiconductor device of claim 1 is performed at time of execution.
